(19) United States
(12) Patent Application Publication
(10) Pub. No.: US 2007/0278579 A1
(43) Pub. Date: Dec. 6, 2007

(54) Protective assembly

(76) Inventors: Vincent Cannistraro, Lincoln, MA (US); Thomas Kosik, Pelham, NH (US)

Correspondence Address: BOURQUE & ASSOCIATES;INTELLECTUAL PROPERTY ATTORNEYS, P.A., 835 HANOVER STREET, SUITE 301, MANCHESTER, NH, 03104, US

(21) Appl. No.: 11/445,905

(22) Filed: Jun. 2, 2006

(51) Int. Cl. H01L 23/62

(52) U.S. Cl. 257/355

(57) ABSTRACT

A protective device for use with a metal stud features a body region, a reduced region, and a passageway disposed therethrough. The reduced region has an outer cross-section that is smaller than the outer cross-section of the body region and is sized and shaped to fit within an aperture disposed within the metal stud. The body region has a length that is at least as long as the thickness of the metal stud.

### TECHNICAL FIELD

The present invention relates to conduit protection devices and more particularly, relates to conduit protective devices for use with metal studs and the like.

### BACKGROUND INFORMATION

The use of metal studs has recently become increasing popular in both commercial as well as residential construction projects. A typical metal stud 1, FIG. 1, features a central region 2 and two legs 3, 4 extending generally perpendicularly outwardly therefrom. The legs 3, 4 generally have a distance D1 that is less than the distance D2 of the central region 2 (typically about ⅓ the distance) and often include regions 5, 6 that extend perpendicularly inwards and towards each other which substantially increase the overall strength of the metal stud 1. Together, the central region 2 and the legs 3, 4 define a central cavity or channel 7.

In practice, the metal stud 1 is generally placed longitudinally upright with a wall structure and the face of the wall (for example sheet rock, plywood, planks, or the like) are secured against one of the outer faces 8 of the legs 3, 4 using screws 9 (typically self-piercing metal “speed screws” or the secured against one of the outer faces 8 of the legs 3, 4 using screws 9 (typically self-piercing metal “speed screws” or the like) as is well known in the construction industry. These screws 9 generally extend into the cavity 7.

During construction, it is often necessary to run conduits such as, but not limited to, plumbing and electrical pipes as well we wires (not shown) through apertures 10 disposed within the central region 2 of the metal stud 1. For ease of installation, the apertures 10 and conduits are often placed within the metal studs 1 prior to securing the facing of the wall to the metal stud 1. Unfortunately, if the screws 9 used to secured the facing of the wall to the metal stud 1 are inserted near a conduit or wire, the screw 9 can easily pierce and damage the conduit or wire. Often times, the damage is not detectable until after the wall has been fully constructed.

It is known to protect conduits and wires from damage. However, most of the known devices are either intended for wood (and therefore not applicable to metal studs 1) or are expensive, complex and require the user to assemble several different parts using bolts or the like.

Accordingly, what is needed is a protective device that is particularly suited for use with metal studs. The protective device should be inexpensive and easy to use. The protective device should not require specialized tools or require complex assembly.

It is important to note that the present invention is not intended to be limited to a system or method which must satisfy one or more of any stated objects or features of the invention. It is also important to note that the present invention is not limited to the preferred, exemplary, or primary embodiment(s) described herein. Modifications and substitutions by one of ordinary skill in the art are considered to be within the scope of the present invention, which is not to be limited except by the following claims.

### SUMMARY

According to one embodiment, the present invention features a protective device for use with a metal stud having a length, a width and a thickness. The protective device includes a body and a reduced region. The body defines a first passage disposed along a longitudinal axis of the body and has a length that is at least equal to the thickness of the metal stud. The reduced region is disposed proximate a first end of the body and defines a second passageway fluidly coupled to the first passageway. The outer cross-section of the reduced region is smaller than an outer cross-section of the body.

The body preferably includes a shoulder region proximate an interface between the body and the reduced region and has a length that is greater than a length of the reduced region. The outer cross-section of the reduced region is preferably substantially circular. The reduced region may include a tapered and/or threaded outer surface.

The first and the second passageways preferably include a first and a second opening disposed about generally opposite ends of the protective device and are preferably generally cylindrical. The body and the reduced region also preferably substantially enclose the first and the second passageways.

According to another embodiment, the present invention features a protective device for use with an aperture in a metal stud having a length, a width and a thickness. The protective device includes a body, a reduced region, and a passageway disposed along a longitudinal axis of the protective device. The body has a length that is at least equal to the thickness of the metal stud and the reduced region is disposed proximate a first end of the body and includes an outer cross-section that is smaller than an outer cross-section of the body. The passageway includes a first and a second opening disposed about generally opposite ends of the protective device.

According to yet a further embodiment, the present invention features a protective device including means for securing to the protective device within an aperture disposed in a central region of a metal stud, means for extending through the thickness of the metal stud, the means having an outer cross-section that is larger than the aperture in the metal stud, and a passageway disposed along a longitudinal axis of the protective device, the passageway having a first and a second opening disposed about generally opposite ends of the protective device.

### BRIEF DESCRIPTION OF THE DRAWINGS

These and other features and advantages of the present invention will be better understood by reading the following detailed description, taken together with the drawings wherein:

FIG. 1 is an end perspective view of one embodiment of a typical prior art metal stud;

FIG. 2 is a top end perspective view of one embodiment of the protective device according to the present invention in combination with a metal stud;

FIG. 3 is a side perspective view of one embodiment of the protective device according to the present invention;

FIG. 4 is a side plan view of another embodiment of the protective device having a tapered reduced region according to the present invention;

FIG. 5 is a side plan view of another embodiment of the protective device wherein the reduced region includes a threaded outer surface according to the present invention; and

FIG. 6 is a side plan view of another embodiment of the protective device wherein the reduced region includes at least one protrusion or rib according to the present invention.

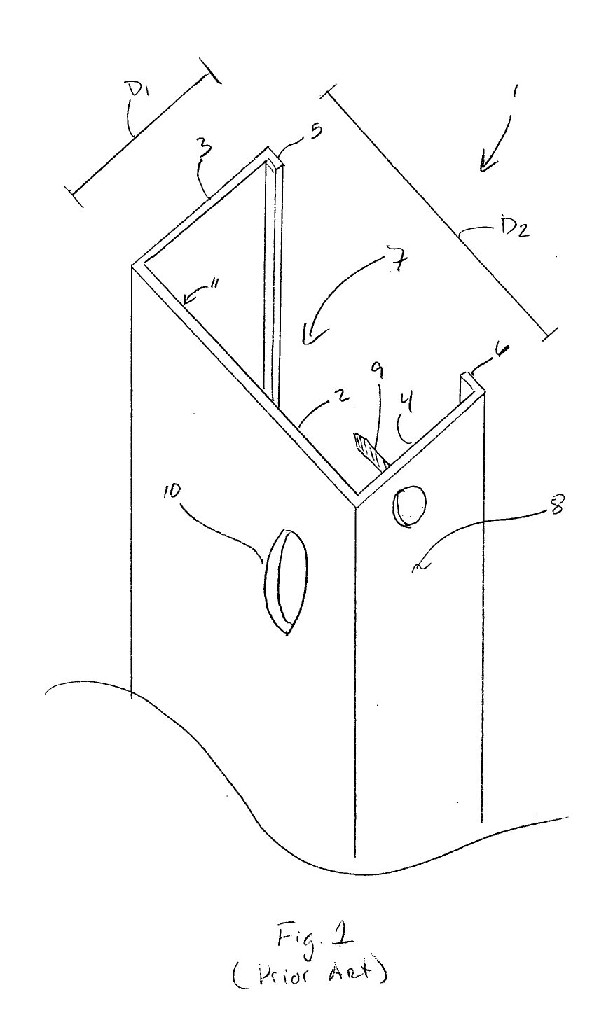

### DETAILED DESCRIPTION OF THE PREFERRED EMBODIMENTS

A protective device 20, FIG. 2, is particularly suited for protecting a conduit (such as, but not limited to, an electrical or fluid conduit) or wire 22 disposed through an aperture 10 in a metal stud 1 (as described above) from damage from a screw 9. In the preferred embodiment, the aperture 10 is disposed in the central region 2, though this is not a limitation of the present invention and the aperture 10 may be disposed through the legs 3, 4. The protective device 20 preferably features a body 24, a reduced region, and at least one passageway 28 disposed therethrough.

As used wherein, the thickness of the metal stud is intended to be the length of the metal stud 1 which the protective device 20 passes through. More specifically, in the embodiment wherein the protective device 20 is disposed within an aperture 10 in the central region 2, the thickness is defined to be the length D1 of the legs 3, 4.

Referring specifically to FIG. 3, the passageway 28 preferably extends along a longitudinal axis L of the protective device 20 and includes a first and at least a second opening 30, 32 disposed about generally opposite ends 31, 33 of the protective device 20. The body 24 of the protective device 20 preferably features a length L1 that is equal to or greater than the thickness of the metal stud 1 and is preferably constructed from a very hard material such a metal or the like. Because the body 24 extends at least through the thickness of the metal stud 1, any screws 9 that are accidentally inserted proximate the protective device 20 will contact the body 24 which has sufficient hardness to prevent the screw 9 from penetrating the passageway 28. The body 24 preferably has a generally tubular outer cross-section, though the body 24 may include any other shape known to those skilled in the art.

The reduced region 26 preferably has a length L2 that is equal to or greater than the thickness of the aperture 10. In the preferred embodiment, the reduced region 26 has a length L2 that large enough such that the reduced region 26 extends just past the outer surface of the metal stud 1. The length L2 is preferably less than the length L1 of the body 24. A benefit of this arrangement is that less force is required to insert or secure the protective device 20 within the aperture 10 of the metal stud 1. The reduced region 26 also features an outer cross-section D3 that substantially the same as the cross-section of the aperture 10 and is preferably smaller than the outer cross-section D4 of the body 24. The outer cross-section D3 is preferably large enough to generate enough friction with the aperture 10 to hold the protective device 20 within the aperture 10. Optionally, an adhesive, bonding agent, solder, or the like may be used to secure the reduced region 26 within the aperture 10.

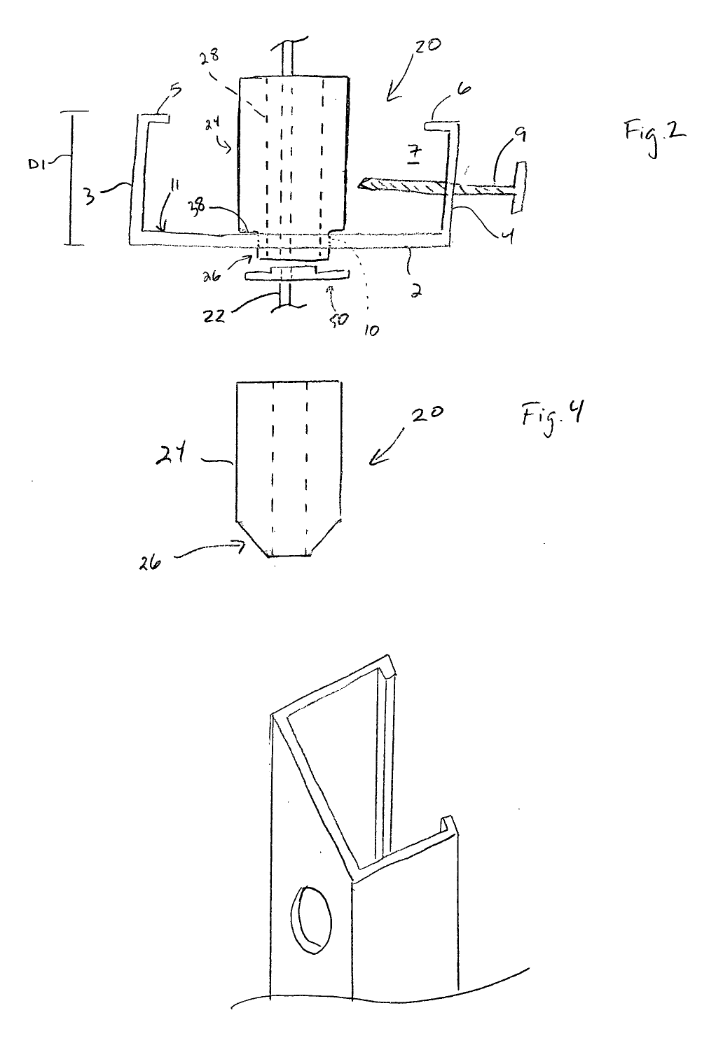

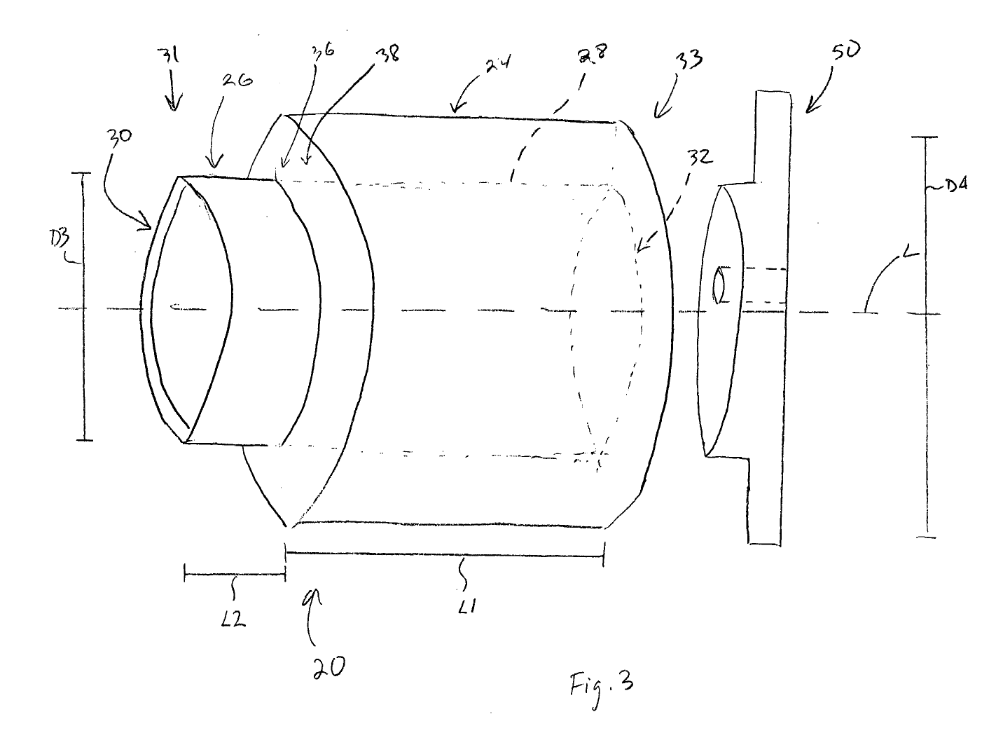

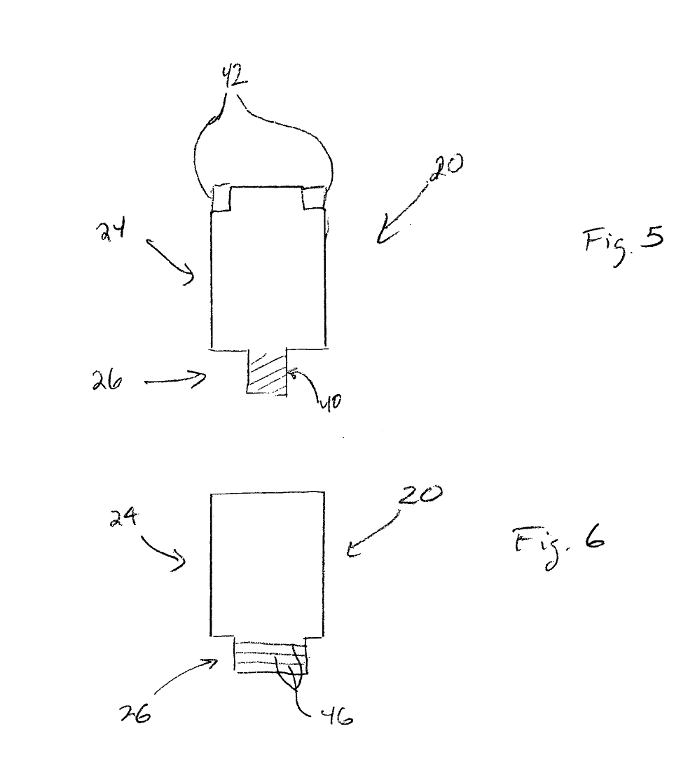

The reduced region 26 preferably has a generally cylindrical or tubular outer shape. Alternatively, the reduced region 26, FIG. 4, may feature a tapered or conical shape and/or may include a threaded outer surface 40, FIG. 5. In the embodiment wherein the protective device 20 includes a threaded outer surface 40, at least a portion of the body 24 preferably includes a non-cylindrical region 42. The non-cylindrical region 42 preferably features a multi-faceted surface adapted to engage a wrench or the like, and is preferably used to rotate the protective device 20 and thread the reduced region 26 into the aperture 10. According to yet another embodiment, the reduced region 26 may include one or more ribs or protrusions 46 that frictionally engage the aperture 10 when the protective device 20 is inserted within the aperture 10.

The interface 36 between the body 24 and the reduced region 26 preferably forms a rim, shoulder, or flanged region 38. Referring to FIG. 2, the reduced region 26 is inserted into the aperture 10 in the metal stud 1 until the rim 38 is substantially against the inner surface 11 of the metal stud 1, preferably the inner surface 11 of the central region 2. Because the reduced region 26 is disposed within the aperture 10, the body 24 extends through the cavity 7 of the metal stud 1 and through the thickness of the metal stud 1. As discussed above, because the length L2 of the reduced region 26 is approximately the same as the thickness of the aperture 10, the force required to insert/secure the protective device 20 within the metal stud 1 is reduced.

The protective device 20, FIGS. 2 and 3, may optionally include a bushing 50 or the like. The bushing 50 is preferably sized and shaped to fit within the second opening of the passageway 28, though it could also be sized and shaped to fit within the first opening 30. Alternatively, the bushing 50 may be sized and shaped to fit over the ends 31, 33 of the protective device 20. In any event, the bushing 50 preferably positively locates the conduit or wires 22 within the passageway 28 and prevents damage to the conduit/wires 22 and may include any bushing design known to those skilled in the art.

Accordingly, the present invention features a protective device that is particularly suited for use with metal studs. The protective device is inexpensive and easy to use and does not require specialized tools or require complex assembly. As mentioned above, the present invention is not intended to be limited to a system or method which must satisfy one or more of any stated or implied object or feature of the invention and should not be limited to the preferred, exemplary, or primary embodiment(s) described herein. The foregoing description of a preferred embodiment of the invention has been presented for purposes of illustration and description. It is not intended to be exhaustive or to limit the invention to the precise form disclosed. Obvious modifications or variations are possible in light of the above teachings. The embodiment was chosen and described to provide the best illustration of the principles of the invention and its practical application to thereby enable one of ordinary skill in the art to utilize the invention in various embodiments and with various modifications as is suited to the particular use contemplated. All such modifications and variations are within the scope of the invention as determined by the claims when interpreted in accordance with breadth to which they are fairly, legally and equitably entitled.

The invention claimed is:

1. A protective device for use with a metal stud having a length, a width and a thickness, said protective device comprising:
a body defining a first passage disposed along a longitudinal axis of said body, said body having a length that is at least equal to said thickness of said metal stud; and
a reduced region disposed proximate a first end of said body and defining a second passageway fluidly coupled to said first passageway, said reduced region having an outer cross-section that is smaller than an outer cross-section of said body.

2. The protective device as claimed in claim 1 wherein said body includes a shoulder region proximate an interface between said body and said reduced region.

3. The protective device as claimed in claim 2 wherein said outer cross-section of said reduced region is substantially circular.

4. The protective device as claimed in claim 3 wherein said length of said body is greater than a length of said reduced region.

5. The protective device as claimed in claim 1 wherein first and said second passageway include a first and a second opening disposed about generally opposite ends of said protective device

6. The protective device as claimed in claim 5 wherein said body and said reduced region substantially enclose said first and said second passageways, respectively.

7. The protective device as claimed in claim 6 wherein said first and said second passageways are generally cylindrical.

8. The protective device as claimed in claim 7 wherein said first and said second passageways having substantially the same inner diameters.

9. The protective device as claimed in claim 6 wherein said reduced region has a generally cylindrical outer shape.

10. The protective device as claimed in claim 9 wherein said body has a generally cylindrical outer shape.

11. The protective device as claimed in claim 1 wherein said reduced region includes a threaded outer surface.

12. The protective device as claimed in claim 1 wherein said reduced region includes a tapered outer surface.

13. A protective device for use with an aperture in a metal stud having a length, a width and a thickness, said protective device comprising:
a body having a length that is at least equal to said thickness of said metal stud; and
a reduced region disposed proximate a first end of said body, said reduced region having an outer cross-section that is smaller than an outer cross-section of said body; and
a passageway disposed along a longitudinal axis of said protective device, said passageway having a first and a second opening disposed about generally opposite ends of said protective device.

14. The protective device as claimed in claim 13 wherein said outer shape of said reduced region is generally cylindrical.

15. The protective device as claimed in claim 13 wherein said outer shape of said reduced region is generally tapered.

16. The protective device as claimed in claim 15 wherein said body further includes a non-cylindrical outer surface.

17. The protective device as claimed in claim 13 wherein a length of said reduced region is smaller than said length of said body.

18. A protective device comprising:
means for securing to said protective device within an aperture disposed in a central region of a metal stud;
means for extending through said thickness of said metal stud, said means having an outer cross-section that is larger than said aperture in said metal stud; and
a passageway disposed along a longitudinal axis of said protective device, said passageway having a first and a second opening disposed about generally opposite ends of said protective device.

19. The protective device as claimed in claim 18 further including a rim disposed about an interface between said means for securing and said means for extending.

20. The protective device as claimed in claim 18 wherein means for securing further includes an outer cross-section that is tapered.
